(19) United States
(12) Patent Application Publication
(10) Pub. No.: US 2026/0107801 A1
(43) Pub. Date: Apr. 16, 2026

(54) SEMICONDUCTOR PACKAGE

(71) Applicant: SAMSUNG ELECTRONICS CO., LTD., Suwon-si (KR)

(72) Inventors: Jaesung LEE, Suwon-si (KR); Dowan KIM, Suwon-si (KR); Un-Byoung KANG, Suwon-si (KR); Seokbong PARK, Suwon-si (KR); Ha-Kyeong LEE, Suwon-si (KR)

(21) Appl. No.: 19/203,933

(22) Filed: May 9, 2025

(30) Foreign Application Priority Data
Oct. 10, 2024 (KR) 10-2024-0137658

(51) Int. Cl. H01L 23/498; H01L 23/00; H01L 23/29; H01L 23/31

(52) U.S. Cl. CPC H10W 70/65; H10W 70/66; H10W 74/114; H10W 74/473; H10W 90/401; H10W 74/10; H10W 90/724

(57) ABSTRACT

A semiconductor package according to some embodiments includes a first redistribution layer including a plurality of redistribution patterns, a semiconductor chip on the first redistribution layer, a second redistribution layer including a plurality of redistribution patterns on the semiconductor chip, and a plurality of conductive posts extending in a first direction between the first redistribution layer and the second redistribution layer to connect the first redistribution layer and the second redistribution layer, wherein each of the plurality of conductive posts includes a first portion and a second portion on the first portion, and the second portion includes at least one first space positioned inside the second portion and at least one second space connecting the at least one first space to an outer side surface of the second portion.

### CROSS-REFERENCE TO RELATED APPLICATION

This application claims priority to and the benefit of Korean Patent Application No. 10-2024-0137658, filed at the Korean Intellectual Property Office on Oct. 10, 2024, the entire contents of which are incorporated herein by reference.

### FIELD

The present disclosure relates to a semiconductor package.

### BACKGROUND

With the recent miniaturization of electronic devices, semiconductor devices are becoming smaller, thinner, and lighter. In addition, semiconductor packages in which multiple semiconductor devices are mounted are becoming increasingly highly integrated.

In the case of panel level package (PLP) and wafer level package (WLP) products among semiconductor packages, pillar-shaped conductive posts may be used for electrical connection of a frontside redistribution layer (FRDL) and a backside redistribution layer (BRDL).

A conductive post may be disposed between the frontside redistribution layer and the backside redistribution layer, and the remaining region between the frontside redistribution layer and the backside redistribution layer may be filled with an epoxy molding compound (EMC).

### SUMMARY

Example embodiments may provide a highly reliable semiconductor package.

Additionally, example embodiments may prevent a molding material from being delaminated from a conductive post.

A semiconductor package according to some embodiments includes a first redistribution layer including a plurality of redistribution patterns, a semiconductor chip on the first redistribution layer, a second redistribution layer including a plurality of redistribution patterns on the semiconductor chip, and a plurality of conductive posts extending in a first direction between the first redistribution layer and the second redistribution layer to connect the first redistribution layer and the second redistribution layer, wherein each of the plurality of conductive posts includes a first portion and a second portion on the first portion, and the second portion includes at least one first space positioned inside the second portion and at least one second space connecting the at least one first space to an outer side surface of the second portion.

A semiconductor package according to some embodiments includes a first redistribution layer including a plurality of redistribution patterns, a semiconductor chip on the first redistribution layer, a second redistribution layer including a plurality of redistribution patterns on the semiconductor chip, and a plurality of conductive posts extending in a first direction between the first redistribution layer and the second redistribution layer to connect the first redistribution layer and the second redistribution layer, wherein the plurality of conductive posts includes a first portion and a second portion on the first portion and having a pillar shape of n sides (n is an integer greater than or equal to 3), and the second portion includes n first spaces positioned between a center of the second portion and an outer surface of the second portion and n second spaces between the n first spaces and the outer surface of the second portion and positioned at vertices of the second portion.

A semiconductor package according to some embodiments includes a first redistribution layer including a plurality of redistribution patterns, a semiconductor chip on the first redistribution layer, a second redistribution layer including a plurality of redistribution patterns on the semiconductor chip, a plurality of conductive posts between the first redistribution layer and the second redistribution layer and connecting the first redistribution layer and the second redistribution layer, and a molding material at least partially surrounding the plurality of conductive posts and the semiconductor chip between the first redistribution layer and the second redistribution layer, wherein the plurality of conductive posts includes a first portion having a cylindrical shape and a second portion having a cylindrical shape on the first portion, and the second portion includes four first spaces positioned inside the second portion and four second spaces connecting the first spaces to an outer surface of the second portion, the four first spaces and the four second spaces are disposed to be rotationally symmetrical at an angle of 90° based on a center of the second portion, and a width of the first space is larger than a width of the second space, and the molding material fills the four first spaces and the four second spaces.

According to some embodiments, it is possible to provide a highly reliable semiconductor package.

Additionally, according to some embodiments, it is possible to prevent the molding material from being delaminated from the conductive post.

### BRIEF DESCRIPTION OF THE DRAWINGS

FIG. 1 is a top plan view of a semiconductor package according to some embodiments.

FIG. 2 is an example cross-sectional view of a semiconductor package cut along line A-A′ of FIG. 1.

FIG. 3 is an enlarged view of region P of FIG. 2.

FIGS. 4 to 11 illustrate a second portion of a conductive post according to some embodiments.

FIG. 12 is an example diagram of a conductive post according to some embodiments.

FIGS. 13 to 25 are drawings for describing a process for forming a conductive post according to some embodiments.

### DETAILED DESCRIPTION

The present disclosure will be described in detail hereinafter with reference to the accompanying drawings, in which example embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions may be exaggerated for clarity. In the drawings, to facilitate understanding and ease of description, the thicknesses of some layers and regions may be exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is referred to as being “on” or “above” a reference element, it may be positioned above or below the reference element, and it may not necessarily be referred to as being positioned “on” or “above” it in a direction opposite to gravity.

In addition, unless explicitly stated to the contrary, the word “comprise” and variations such as “comprises” and “comprising” should be understood to imply the inclusion of stated elements but not the exclusion of any other elements.

In addition, the phrase “on a plane” means a view from a position above the object (e.g., from the top), and the phrase “in a cross-section” means a view of a cross-section of the object which is vertically cut from the side.

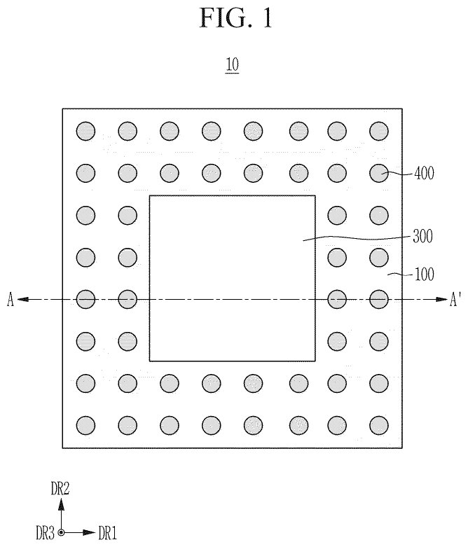

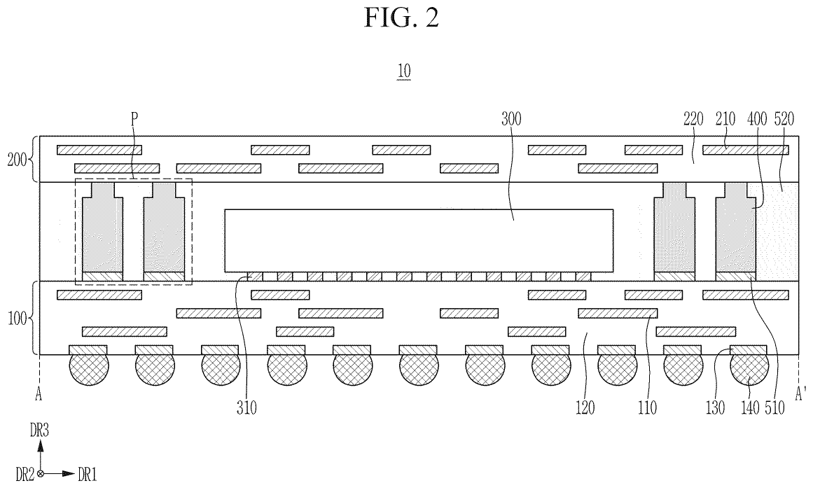

FIG. 1 is a top plan view of a semiconductor package according to some embodiments. FIG. 2 is an example cross-sectional view of a semiconductor package cut along line A-A′ of FIG. 1.

Referring to FIGS. 1 and 2, a semiconductor package 10 according to some embodiments may include a first redistribution layer 100, a second redistribution layer 200, a semiconductor chip 300, a plurality of conductive posts 400, and a molding material 520.

The first redistribution layer 100 may be electrically connected to the semiconductor chip 300 and may perform a redistribution function by receiving a signal from the semiconductor chip 300.

The first redistribution layer 100 may include a first redistribution pattern 110 and a first insulating layer 120. Additionally, the first redistribution layer 100 may include a lower pad 130, and the lower pad 130 may be connected to a connection terminal 140. A plurality of first redistribution patterns 110 may be arranged in the first redistribution layer 100, and the plurality of first redistribution patterns 110 may be arranged in multiple layers, and at least some of the plurality of first redistribution patterns 110 may be electrically connected to each other. At least some of the plurality of first redistribution patterns 110 may be electrically connected to at least some of the plurality of conductive posts 400.

The first redistribution pattern 110 may include, but is not limited to, copper (Cu), aluminum (Al), silver (Ag), tin (Sn), gold (Au), nickel (Ni), lead (Pb), titanium (Ti), or alloys thereof.

The first insulating layer 120 may cover or surround the plurality of first redistribution patterns 110. The first insulating layer 120 may include an insulating material. For example, the first insulating layer 120 may include a photoimageable dielectric (PID). The photosensitive insulating material may include, but is not limited to, photosensitive polyimide, benzocyclobutene-based polymer, photosensitive polybenzoxazole, photosensitive phenol-based polymer, etc. Additionally, for example, the first insulating layer 120 may include, but is not limited to, an insulating material such as at least one of silicon oxide, silicon nitride, and silicon oxynitride.

The first redistribution layer 100 may include a plurality of lower pads 130. The plurality of lower pads 130 may be disposed at the lower portion of the first redistribution layer 100. For example, the lower surfaces of the plurality of lower pads 130 may be positioned at the same level as the lower surface of the first redistribution layer 100, but is not limited thereto.

The plurality of lower pads 130 may be disposed to be spaced apart from each other in the first redistribution layer 100. The side and upper surfaces of the plurality of lower pads 130 may be covered or surrounded by the first insulating layer 120.

The plurality of lower pads 130 may include a conductive material. For example, the plurality of lower pads 130 may include, but are not limited to, copper (Cu), aluminum (Al), silver (Ag), tin (Sn), gold (Au), nickel (Ni), lead (Pb), titanium (Ti), or alloys thereof. At least some of the plurality of lower pads 130 may be electrically connected to at least some of the plurality of first redistribution patterns 110.

A plurality of connection terminals 140 may be respectively connected to the plurality of lower pads 130. The plurality of connection terminals 140 may be solder balls containing tin (Sn) and a tin (Sn) alloy, but are not limited thereto. The connection terminal 140 may have various shapes such as a ball, pin, or pillar.

The semiconductor chip 300 may be disposed on the first redistribution layer 100. For example, the semiconductor chip 300 may be disposed on the upper surface of the first redistribution layer 100.

The semiconductor chip 300 and the first redistribution layer 100 may be electrically connected to each other through a plurality of connection members 310. For example, the connection member 310 may be a solder bump including, but is not limited to, tin (Sn) and a tin (Sn) alloy. The connection member 310 may have various shapes such as a ball, a pin, or a pillar. The connection member 310 may be formed as a single layer or multiple layers.

For example, the semiconductor chip 300 may be a logic semiconductor chip. The logic semiconductor chip may be any one of a gate array, a cell base array, an embedded array, a structured application-specific integrated circuit (ASIC), a field programmable gate array (FPGA), a complex programmable logic device (CPLD), a central processing unit (CPU), a micro processing unit (MPU), a micro controller unit (MCU), a logic IC, an application processor (AP), a driver IC, an RF chip, and a CMOS image sensor. However, it is not limited thereto, and the semiconductor chip 300 may be a memory semiconductor chip.

The second redistribution layer 200 may be disposed on the semiconductor chip 300. The second redistribution layer 200 may be disposed on the first redistribution layer 100. The semiconductor chip 300 may be disposed between the first redistribution layer 100 and the second redistribution layer 200.

The second redistribution layer 200 may include a second redistribution pattern 210 and a second insulating layer 220.

The second redistribution pattern 210 may have similar characteristics to the first redistribution pattern 110 of the first redistribution layer 100. Additionally, the second insulating layer 220 may have similar characteristics to the first insulating layer 120 of the first redistribution layer 100.

The plurality of conductive posts 400 may serve to electrically connect the first redistribution layer 100 and the second redistribution layer 200.

The plurality of conductive posts 400 may be disposed between the first redistribution layer 100 and the second redistribution layer 200. Additionally, the plurality of conductive posts 400 may be disposed to be spaced apart from the semiconductor chip 300. The plurality of conductive posts 400 may be disposed to be spaced apart from each other. The plurality of conductive posts 400 may be disposed to surround the semiconductor chip 300 on a plane extending in the first direction (DR1) and the second direction (DR2), but is not limited thereto. The first direction (DR1), the second direction (DR2), and the third direction (DR3) may be perpendicular to each other.

The conductive post 400 may have a shape extending in the third direction (DR3) and may have a pillar shape. For example, the conductive post 400 may have a polygonal prism or cylinder shape including, but not limited to, a triangular prism, a square prism, a pentagonal prism, and a hexagonal prism.

The conductive post 400 may include a conductive material. For example, the conductive post 400 may include, but is not limited to, copper (Cu), aluminum (Al), silver (Ag), tin (Sn), gold (Au), nickel (Ni), lead (Pb), titanium (Ti), or alloys thereof. For example, the conductive post 400 may be formed of copper (Cu).

A plurality of connection pads 510 may be respectively disposed between the plurality of conductive posts 400 and the first redistribution layer 100. However, unlike as shown in FIG. 2, the plurality of connection pads 510 may be omitted, and the plurality of conductive posts 400 and the first redistribution layer 100 may be directly connected.

The connection pad 510 may serve to electrically connect the conductive post 400 and the first redistribution layer 100 to each other. The connection pad 510 may include a conductive material. For example, the connection pad 510 may include, but is not limited to, copper (Cu), aluminum (Al), silver (Ag), tin (Sn), gold (Au), nickel (Ni), lead (Pb), titanium (Ti), or alloys thereof.

Additionally, for example, the connection pad 510 may include a first metal layer including copper (Cu), a second metal layer positioned on the first metal layer and including nickel (Ni), and a third metal layer positioned on the second metal layer and including gold (Au).

The molding material 520 may be positioned between the first redistribution layer 100 and the second redistribution layer 200. The molding material 520 may cover or surround the semiconductor chip 300 and the plurality of conductive posts 400. For example, the molding material may cover the upper and side surfaces of the semiconductor chip 300 and may cover the side surfaces of the plurality of conductive posts 400.

The molding material 520 may include epoxy molding compound (EMC). The EMC may contain epoxy resin and filler.

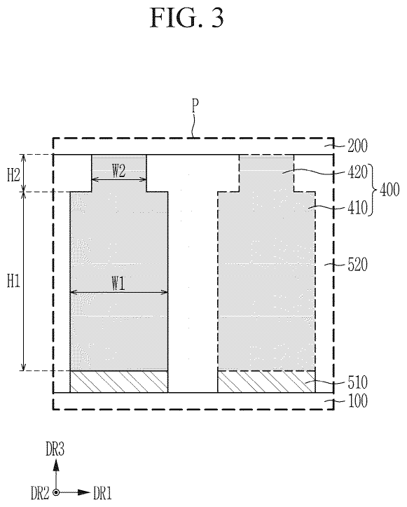

FIG. 3 is an enlarged view of region P of FIG. 2.

Referring to FIG. 3, the conductive post 400 may include a first portion 410 and a second portion 420 positioned on the first portion 410. The first portion 410 and the second portion 420 may each include, but are not limited to, copper (Cu), aluminum (Al), silver (Ag), tin (Sn), gold (Au), nickel (Ni), lead (Pb), titanium (Ti), or alloys thereof.

The first portion 410 and the second portion 420 may each have a polygonal prism or cylinder shape including, but not limited to, a triangular prism, a square prism, a pentagonal prism, and a hexagonal prism.

The width of the first portion 410 may be a first portion width W1, and the height of the first portion 410 may be a first portion height H1. The width of the second portion 420 may be a second portion width W2, and the height of the second portion 420 may be a second portion height H2. For example, the first portion width W1 may be greater than the second portion width W2, and the first portion height H1 may be greater than the second portion height H2, but is not limited thereto.

For example, the sum of the first portion height H1 and the second portion height H2 may be about 350 μm or more and about 400 μm or less. The ratio of the first portion height H1 and the second portion height H2 may be, but is not limited to, 5:1. For example, the first portion height H1 may be about 280 μm or more and 350 μm or less, and the second portion height H2 may be about 50 μm or more and 70 μm or less. Additionally, for example, if the first portion width W1 is about 180 μm, the second portion width W2 may be about 100 μm or more and about 150 μm or less, but is not limited thereto.

In FIG. 3, the width of the connection pad 510 is shown as being the same as the first portion width W1, but is not limited thereto. For example, the width of the connection pad 510 may be greater than the first portion width W1. For example, if the first portion width W1 is 180 μm, the width of the connection pad 510 may be 200 μm.

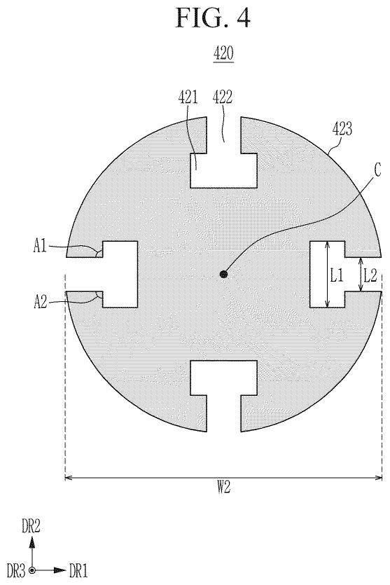

FIGS. 4 to 11 illustrate a second portion of a conductive post according to some embodiments.

Referring to FIG. 4, the second portion 420 of the conductive post 400 according to some embodiments may have a circular shape on a plane. And, the second portion 420 may have a cylindrical shape. Additionally, the second portion 420 may include one or more first spaces or first openings 421 and second spaces or second openings 422 corresponding to the first spaces 421.

The first space 421 and the second space 422 may mean spaces or openings extending in the third direction (DR3). For example, four first spaces 421 and four second spaces 422 may be disposed in the second portion 420.

The first space 421 may mean a space positioned within the second portion 420 (e.g., between a center C of the second portion 420 and an outer side surface 423 of the second portion). For example, the first space 421 may have a quadrangle shape on a plane as shown in FIG. 4, but is not limited thereto. The second space 422 may mean a space that connects the first space 421 and the exterior from the second portion 420. The second space 422 may extend outwardly from the first space 421 to the outer surface or outer side surface 423 of the second portion 420. The second space 422 may be between the first space 421 and the outer side surface 423 of the second portion.

The first space 421 and the second space 422 may be filled with the molding material 520, and for example, the molding material 520 filled in the first space 421 may be supplied to the first space 421 through the second space 422.

On a plane, the width of the first space 421 may be a first space width L1, and a width of the second space 422 may be the second space width L2. The first space width L1 may be larger than the second space width L2. For example, the second space width L2 may be about 10 μm or more and about 20 μm or less, and the first space width L1 may be about 30 μm or more and about 50 μm or less, which is larger than the second space width L2, but is not limited thereto. In order to allow the filler included in the molding material 520 to be filled in the first space 421 and the second space 422, the second space width L2 may be larger than the diameter of the filler included in the molding material 520. Additionally, the first space width L1 may also be larger than the diameter of the filler included in the molding material 520. That is, the first space 421 and the second space 422 may have a size that may be filled with the molding material 520.

Referring to FIG. 4, for example, on a plane, the second space 422 may be in contact with the first space 421 at the center of the first space 421 to form a space having an uneven shape or a “T”shape, but is not limited thereto.

The first space 421 and the second space 422 may be in contact with each other on a plane to form a first angle A1 on one side of the second space 422 and a second angle A2 on the other side of the second space 422. Referring to FIG. 4, the first angle A1 and the second angle A2 may be equal to each other and may be 90°, but are not limited thereto. For example, the first angle A1 and the second angle A2 may be greater than 0° and less than 180°, respectively.

The first space 421 and the second space 422 corresponding to the first space 421 may be disposed rotationally symmetrically based on the center of the second portion 420 within the second portion 420. For example, referring to FIG. 4, the first space 421 and the second space 422 may be disposed with 90° rotational symmetry, but is not limited thereto. The second portions 420 may be circumferentially spaced apart from one another with a central angle of 90° between adjacent ones of the second portions 420.

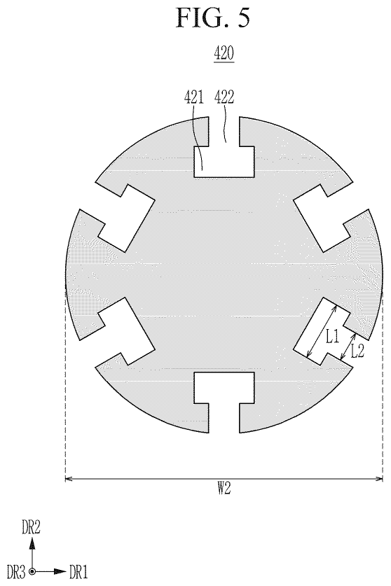

Referring to FIG. 5, for example, in the second portion 420, six first spaces 421 and six second spaces 422 may be disposed with 60° rotational symmetry. The second portions 420 may be circumferentially spaced apart from one another with a central angle of 60° between adjacent ones of the second portions 420.

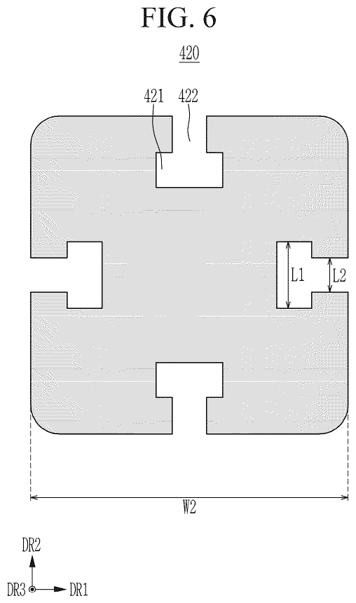

Referring to FIG. 6, for example, the second portion 420 may have a square shape with rounded vertices or corners on a plane. Additionally, the second portion 420 may have a square pillar shape. The first space 421 and the second space 422 may be disposed so that the second space 422 is positioned on each side of a square on a plane.

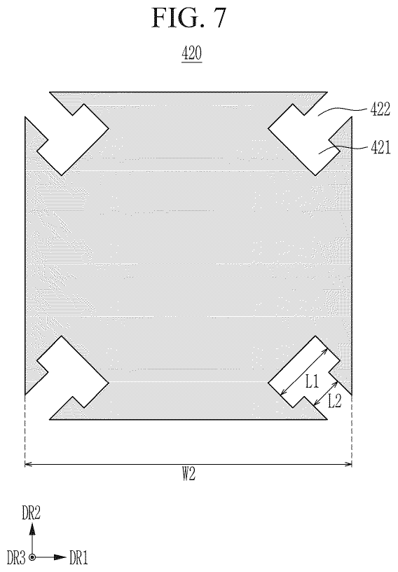

Referring to FIG. 7, for example, the second portion 420 may have a square shape on a plane, and the second portion 420 may have a square pillar shape. The first space 421 and the second space 422 may be disposed so that the first space 421 and the second space 420 are positioned at each vertex or corner of a square on a plane.

Additionally, the second portion 420 of the conductive post 400 may have a pillar shape of n angles (n is an integer greater than or equal to 3). The second portion 420 may include n first spaces 421 positioned inside and n second spaces 422 connecting the n first spaces 421 and the exterior of the second portion 420 (or an outer side surface of the second portion 420) and positioned at vertices or corners of the second portion 420. Here, the n first spaces 421 and the n second spaces 422 may extend in the third direction (DR3). The n first spaces 421 and the n second spaces 422 may be disposed to be rotationally symmetrical at an angle of 360°/n within the second space 420.

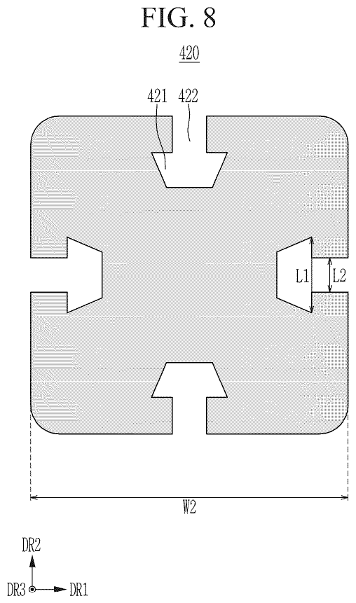

Referring to FIG. 8, for example, the first space 421 may have a trapezoidal shape, but is not limited thereto.

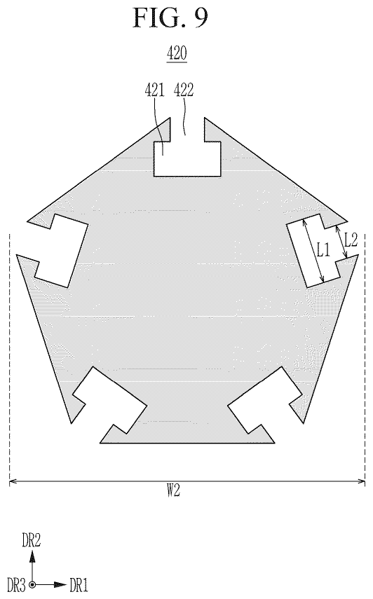

Referring to FIG. 9, for example, the second portion 420 may have a pentagonal shape on a plane. The second portion 420 may have a pentagonal prism shape. For example, five first spaces 421 and five second spaces 422 may be disposed within the second portion 420. The first space 421 and the second space 422 may be disposed so that the second space 422 is positioned at each vertex of a pentagon on a plane. Additionally, for example, the first space 421 and the second space 422 may be disposed with 72° rotational symmetry. Additionally, unlike as shown, the first space 421 and the second space 422 may also be disposed so that the second space 422 is positioned on each side of a pentagon on a plane.

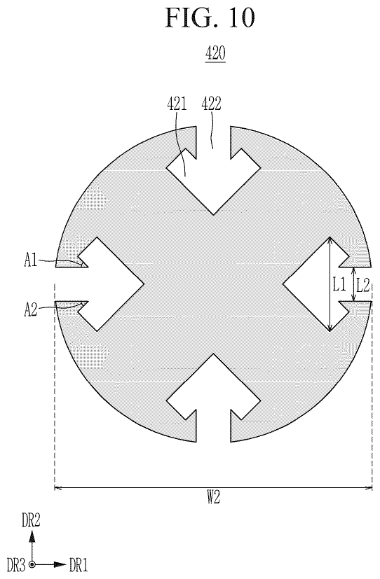

Referring to FIG. 10, for example, the first space 421 may have a V shape on a plane. The first space 421 may have a V-shaped pillar shape. The first space 421 and the second space 422 may be in contact with each other to form an arrow-shaped space or opening. The first angle A1 and the second angle A2 formed when the first space 421) and the second space 422 meet each other may be acute angles less than 90°.

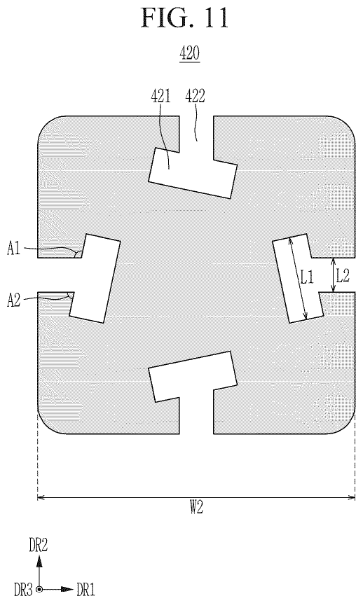

Referring to FIG. 11, the first angle A1 and the second angle A2 formed when the first space 421 and the second space 422 meet each other may be different. For example, the first angle A1 may be an obtuse angle and the second angle A2 may be an acute angle. Alternatively, the first angle A1 may be an acute angle and the second angle A2 may be an obtuse angle. Additionally, the first space 421 and the second space 422 may be disposed left-right symmetrically, up-down symmetrically, or asymmetrically, rather than rotationally symmetrically.

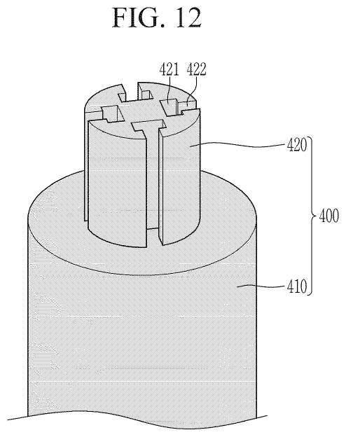

FIG. 12 is an example diagram of a conductive post according to some embodiments.

Referring to FIG. 12, the conductive post 400 according to some embodiments may include the first portion 410 and the second portion 420. The second portion 420 may include one or more first spaces 421 and one or more second spaces 422. The first space 421 and the second space 422 may have a shape extending in the third direction (DR3).

The molding material 520 may cover the side surface of the conductive post 400 and fill the interior of the first space 421 and the second space 422 of the second portion 420. For example, the molding material 520 may be the EMC containing an epoxy resin and a filler. For example, a semi-liquid-state molding material 520 may be supplied into the interior of the first space 421 and the second space 422, and then heat and pressure may be applied to cure the molding material 520. Accordingly, the molding material 520 may be in a state of mechanical interlocking with the conductive post 400, and the molding material 520 may be prevented from being delaminated from the conductive post 400.

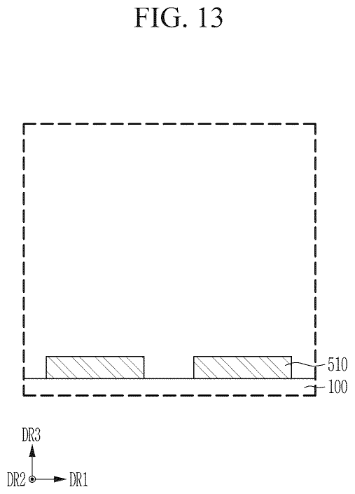

FIGS. 13 to 25 are drawings for describing a process for forming a conductive post according to some embodiments.

Referring to FIG. 13, the plurality of connection pads 510 may be disposed on the first redistribution layer 100. For convenience of description, the plurality of connection pads 510 are illustrated as being positioned on the first redistribution layer 100, but it is not limited thereto, and the plurality of connection pads 510 may be positioned within the first redistribution layer 100.

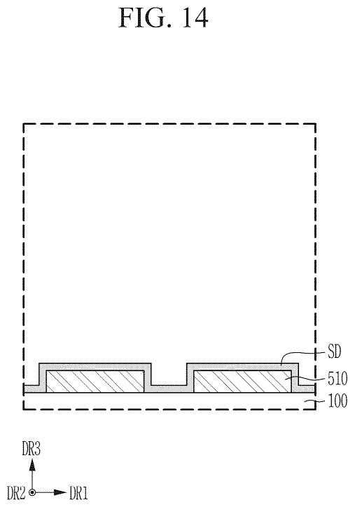

Referring to FIG. 14, a seed layer SD may be deposited on the plurality of connection pads 510. Here, the seed layer SD may include the same material as the material included in the conductive post 400. For example, the seed layer SD may include, but is not limited to, copper (Cu), aluminum (Al), silver (Ag), tin (Sn), gold (Au), nickel (Ni), lead (Pb), titanium (Ti), or alloys thereof. Additionally, the seed layer SD may also be deposited on the first redistribution layer 100 during the process of being deposited on the connection pad 510.

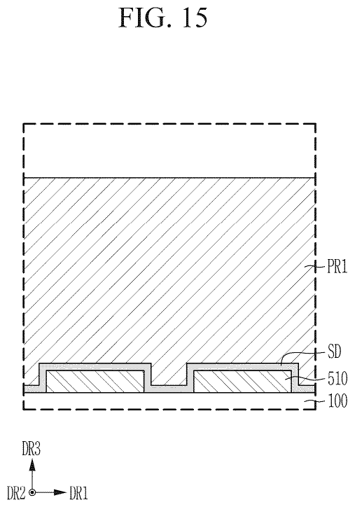

Referring to FIG. 15, a first photoresist layer PR1 may be formed on the seed layer SD. In the following description, for convenience, it is assumed that the photoresist material used in the first photoresist layer PR1 is of a negative type, but it is not limited thereto, and a positive type photoresist material may be used in the first photoresist layer PR1.

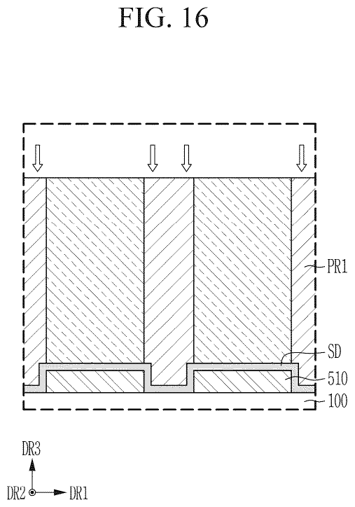

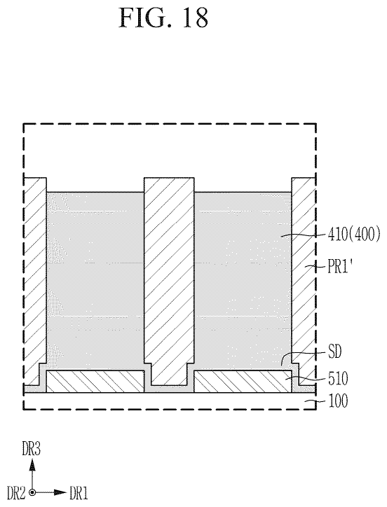

Referring to FIG. 16, an exposure process may be performed to supply light to the remaining region except for the region where the first portion 410 of FIG. 18 is to be disposed on the first photoresist layer PR1.

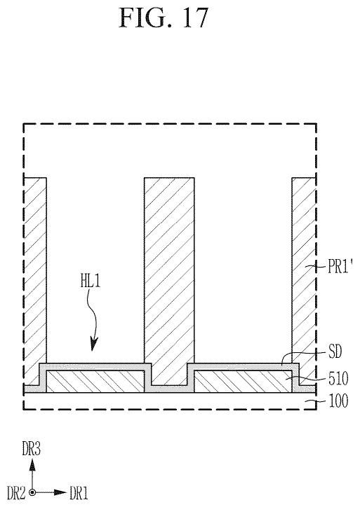

When a development process is performed on the first photoresist layer PR1 that has undergone an exposure process, as illustrated in FIG. 17, a portion of the first photoresist layer PR1 may be removed to form a first photoresist pattern PR1′ including a first opening HL1 vertically overlapping the connection pad 510. At least a portion of the upper surface of the seed layer SD positioned on the connection pad 510 may be exposed to the outside through the first opening HL1.

Referring to FIG. 18, the first portion 410 of the conductive post 400 may be formed within the first opening HL1. For example, the first portion 410 positioned within the first opening HL1 may be formed using electroplating.

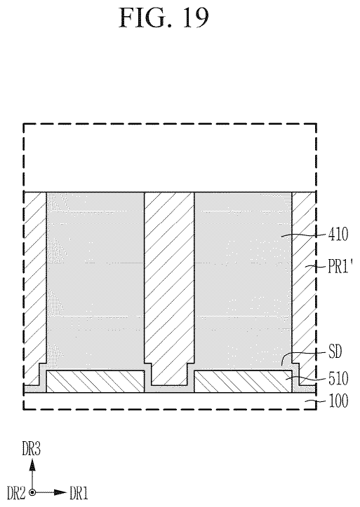

Referring to FIG. 19, a planarization process may be performed to planarize the upper surface of the first photoresist pattern PR1′ and the upper surface of the first portion 410. For example, the planarization process may be a grinding or a chemical mechanical polishing (CMP) process.

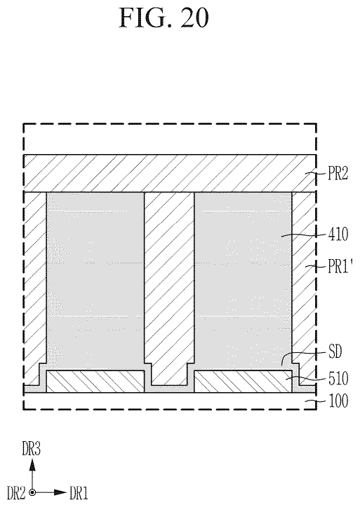

Referring to FIG. 20, a second photoresist layer PR2 may be formed on the first photoresist pattern PR1′ and the first portion 410. In the following description, for convenience, it is assumed that the photoresist material used in the second photoresist layer PR2 is a negative type, but it is not limited thereto, and a positive type photoresist material may be used in the second photoresist layer PR2.

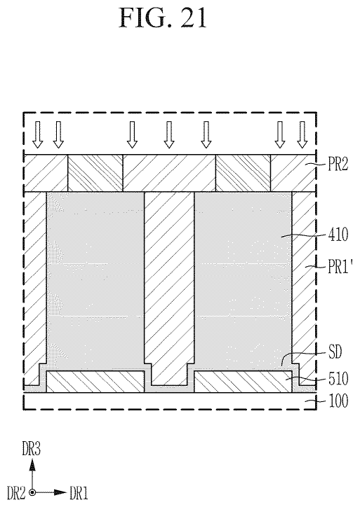

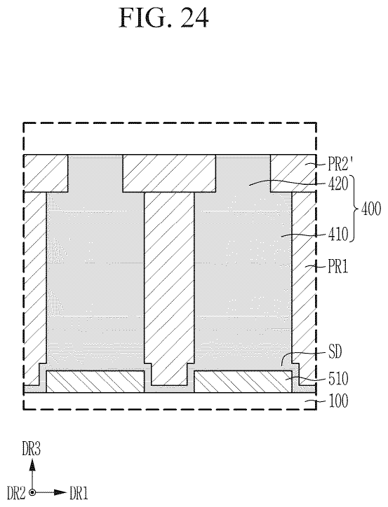

Referring to FIG. 21, an exposure process may be performed to supply light to the remaining region except for the region where the second portion 420 of FIG. 24 is to be disposed on the second photoresist pattern PR2.

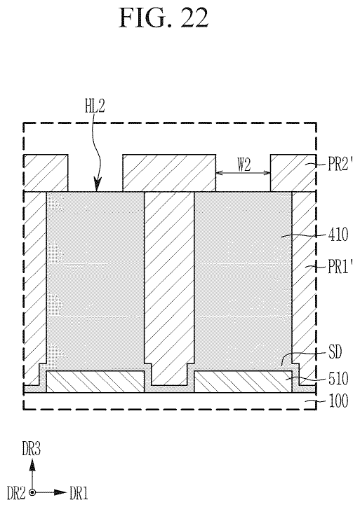

Referring to FIG. 22, when a development process is performed on the second photoresist layer PR2 that has undergone an exposure process, as illustrated in FIG. 22, a portion of the second photoresist layer PR2 may be removed to form a second photoresist pattern PR2′ positioned on the first portion 410 and the first photoresist pattern PR1′ and including a second opening HL2. At least a portion of the first portion 410 may be exposed to the outside by the second opening HL2.

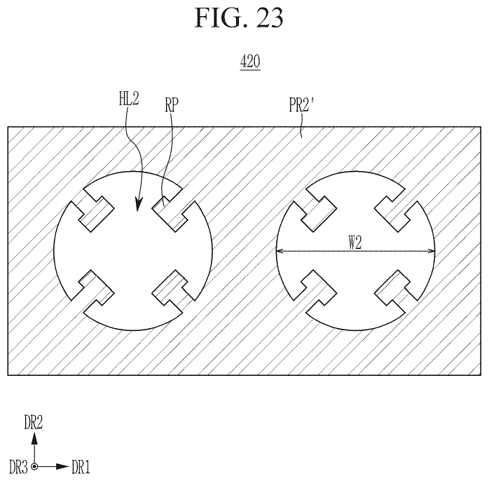

Referring to FIG. 23, a residual pattern RP corresponding to the first space 421 and the second space 422 of the second photoresist pattern PR2′ may remain in the second opening HL2 formed through the development process for the second photoresist pattern PR2′.

Referring to FIG. 24, the second portion 420 of the conductive post 400 may be formed within the second opening HL2. For example, the second portion 420 positioned within the second opening HL2 may be formed using electroplating. Additionally, the second portion 420 may have the first space 421 and the second space 422 formed by the residual pattern RP of the second photoresist pattern PR2′.

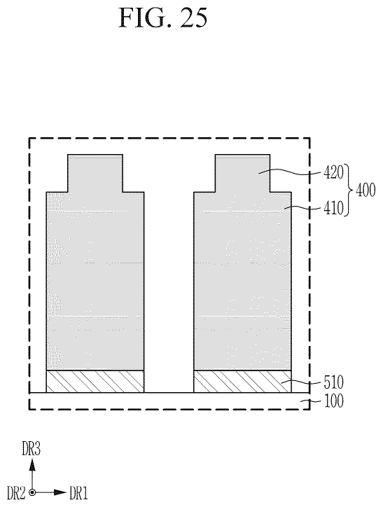

Referring to FIG. 25, a strip process for removing the first photoresist pattern PR1 and the second photoresist pattern PR2 and a process for etching the seed layer SD on the first redistribution layer 100 may be performed. Accordingly, the conductive post 400 may be formed on the first redistribution layer 100.

While this disclosure has been described in connection with what is presently considered to be practical embodiments, it should be understood that the disclosure is not limited to the disclosed example embodiments, but, on the contrary, is intended to cover various modifications and equivalent arrangements included within the spirit and scope of the appended claims.

What is claimed is:

1. A semiconductor package, comprising:
a first redistribution layer including a plurality of redistribution patterns;
a semiconductor chip on the first redistribution layer;
a second redistribution layer including a plurality of redistribution patterns on the semiconductor chip; and
a plurality of conductive posts extending in a first direction between the first redistribution layer and the second redistribution layer to connect the first redistribution layer and the second redistribution layer,
wherein each of the plurality of conductive posts includes a first portion and a second portion on the first portion, and the second portion includes at least one first space positioned inside the second portion and at least one second space connecting the at least one first space to an outer side surface of the second portion.

2. The semiconductor package of claim 1, wherein
the first portion and the second portion have a polygonal columnar or cylindrical shape.

3. The semiconductor package of claim 1, wherein
a width of the first portion is greater than a width of the second portion.

4. The semiconductor package of claim 1, wherein
the at least one first space and the at least one second space extend in the first direction in the second portion.

5. The semiconductor package of claim 1, wherein
a width of the at least one first space is greater than a width of the at least one second space.

6. The semiconductor package of claim 1, wherein
a height of the first portion is greater than a height of the second portion.

7. The semiconductor package of claim 1, wherein
the at least one first space and the at least one second space comprise a plurality of first spaces and a corresponding plurality of second spaces, and each first space and corresponding second space are circumferentially spaced apart an equal distance from one another.

8. The semiconductor package of claim 1, comprising:
a molding material surrounding the plurality of conductive posts and the semiconductor chip between the first redistribution layer and the second redistribution layer.

9. The semiconductor package of claim 8, wherein
the molding material fills the at least one first space and the at least one second space.

10. The semiconductor package of claim 8, wherein
the molding material contains epoxy resin and a filler,
and a width of the at least one first space and a width of the at least one second space are larger than a diameter of the filler of the molding material.

11. The semiconductor package of claim 1, wherein
the first space has a rectangular shape or V shape.

12. The semiconductor package of claim 1, wherein
a first angle between the first space and the second space on a first side of the second space and a second angle between the first space and the second space on a second, opposite side of the second space,
and the first angle and the second angle are greater than 0° and less than 180°.

13. The semiconductor package of claim 1, comprising:
a plurality of connection pads between the plurality of conductive posts and the first redistribution layer.

14. The semiconductor package of claim 13, wherein
the plurality of connection pads include a first metal layer including copper (Cu), a second metal layer on the first metal layer and including nickel (Ni), and a third metal layer on the second metal layer and including gold (Au).

15. A semiconductor package, comprising:
a first redistribution layer including a plurality of redistribution patterns;
a semiconductor chip on the first redistribution layer;
a second redistribution layer including a plurality of redistribution patterns on the semiconductor chip; and
a plurality of conductive posts extending in a first direction between the first redistribution layer and the second redistribution layer to connect the first redistribution layer and the second redistribution layer,
wherein the plurality of conductive posts each includes a first portion and a second portion on the first portion and having a pillar shape of n sides (n is an integer greater than or equal to 3), and the second portion includes n first spaces positioned inside the second portion and n second spaces between the n first spaces and an outer surface of the second portion and positioned at vertices of the second portion.

16. The semiconductor package of claim 15, wherein
the n first spaces and the n second spaces extend in the first direction within the second portion.

17. The semiconductor package of claim 15, wherein
the n first spaces and the n second spaces are disposed to be rotationally symmetrical at an angle of 360°/n.

18. The semiconductor package of claim 15, comprising:
a molding material at least partially surrounding the plurality of conductive posts and the semiconductor chip between the first redistribution layer and the second redistribution layer.

19. The semiconductor package of claim 18, wherein
the molding material fills the n first spaces and the n second spaces.

20. A semiconductor package, comprising:
a first redistribution layer including a plurality of redistribution patterns;
a semiconductor chip on the first redistribution layer;
a second redistribution layer including a plurality of redistribution patterns on the semiconductor chip;
a plurality of conductive posts between the first redistribution layer and the second redistribution layer and connecting the first redistribution layer and the second redistribution layer; and
a molding material at least partially surrounding the plurality of conductive posts and the semiconductor chip between the first redistribution layer and the second redistribution layer,
wherein the plurality of conductive posts includes a first portion having a cylindrical shape and a second portion having a cylindrical shape on the first portion, and the second portion includes four first spaces positioned inside the second portion and four second spaces connecting the first spaces to an outer surface of the second portion,
the four first spaces and the four second spaces are disposed to be rotationally symmetrical at an angle of 90° based on a center of the second portion, and a width of the first space is larger than a width of the second space,
and the molding material fills the four first spaces and the four second spaces.
